(19) United States
(12) Patent Application Publication
(10) Pub. No.: US 2007/0145428 A1
(43) Pub. Date: Jun. 28, 2007

(54) ISOLATION TRENCH OF A SEMICONDUCTOR DEVICE

(76) Inventor: Kyoung Jin Lee, Seoul (KR)

Correspondence Address: SHERR & NOURSE, PLLC, 620 HERNDON PARKWAY, SUITE 200, HERNDON, VA, 20170, US

(21) Appl. No.: 11/616,810

(22) Filed: Dec. 27, 2006

(30) Foreign Application Priority Data
Dec. 28, 2005 (KR) 10-2005-0131523

(51) Int. Cl. H01L 29/768

(52) U.S. Cl. 257/244

(57) ABSTRACT

Embodiments relate to a method for forming an isolation trench of a semiconductor device. In embodiments, a method for forming an isolation trench of a semiconductor device may include forming a mask layer pattern on a semiconductor substrate, forming an organic material layer on the semiconductor substrate and the mask layer, and forming an isolation trench having a width defined by the mask layer pattern and an organic material spacer layer formed by etching the organic material layer through an etching process for the organic material layer and the semiconductor substrate.

The present application claims priority under 35 U.S.C. 119 and 35 U.S.C. 365 to Korean Patent Application No. 10-2005-0131523 (filed on Dec. 28, 2005), which is hereby incorporated by reference in its entirety.

### BACKGROUND

As semiconductor devices have become more highly integrated, an isolation distance between devices may be shortened. Accordingly, to isolate increasingly smaller devices, which may not be able to be isolated through typical isolation methods such as local oxidation of silicon (LOCOS), a trench isolation procedure may be used. In the trench isolation procedure, a trench may be formed within a semiconductor substrate, and an insulating material, such as a silicon oxide material, may be filled in the trench. This may result in device isolation.

In a method for manufacturing a related art semiconductor device having a trench isolation layer, a mask layer pattern may be formed on a semiconductor substrate. The semiconductor substrate may be a silicon substrate. The mask layer pattern may expose a surface of the semiconductor substrate at an isolation layer, which may define an active area.

The exposed semiconductor substrate may be etched to a prescribed depth, for example by performing an etching process using the mask layer pattern as an etching mask. An isolation trench may thereby be formed. Then, to repair an inner wall of the trench that may have been damaged through the etching process that formed the trench, a sidewall oxide layer may be formed on the inner sidewall of the trench. A liner nitride layer may be formed on the resultant structure.

An insulating layer may be deposited on the resultant structure, thereby filling the trench. A planarization process may then be performed, for example using a chemical mechanical polishing (CMP) process, such that a pad nitride pattern may be exposed. Then, a remaining pad nitride layer pattern may be removed, thereby forming the trench isolation layer.

According to the related art process of forming the trench isolation layer, a width of the isolation trench may be determined based on the mask layer pattern. However, as the level of integration of semiconductor devices increases, a width of the isolation trench may be gradually narrowed. In particular, if an exposure process is performed using a photoresist film, it may be difficult to form an isolation trench having a narrow width due to a limitation of a photolithography process.

### SUMMARY

Embodiments relate to a method for manufacturing a semiconductor device. Embodiments relate to a method for forming an isolation trench of a semiconductor device.

Embodiments relate to a method for forming an isolation trench of a semiconductor device that may be capable of reducing a width of an isolation trench as small as possible.

In embodiments, a method for forming an isolation trench of a semiconductor device may include forming a mask layer pattern on a semiconductor substrate, forming an organic material layer on the semiconductor substrate and the mask layer, and forming an isolation trench having a width defined by the mask layer pattern and an organic material spacer layer formed by etching the organic material layer through an etching process for the organic material layer and the semiconductor substrate.

In embodiments, the organic material layer may include a bottom antireflective coating (BARC) layer. In embodiments, the mask layer pattern may include a photoresist film. In embodiments, the organic material layer and the semiconductor substrate may be etched through an anisotropic etching scheme.

### BRIEF DESCRIPTION OF THE DRAWINGS

FIGS. 1 and 2 are example sectional diagrams illustrating a method for forming an isolation trench of a semiconductor device according to embodiments.

### DETAILED DESCRIPTION OF EMBODIMENTS

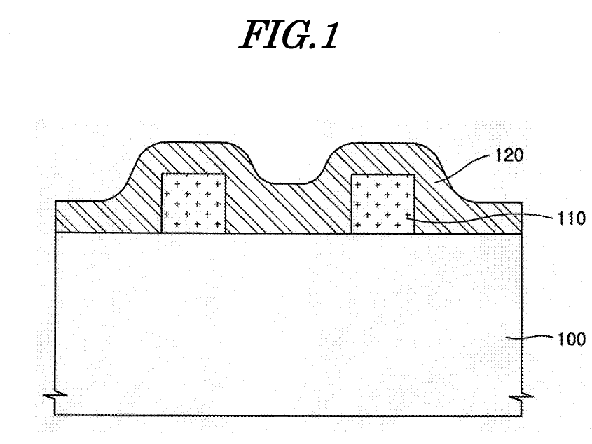

Referring to FIG. 1, mask layer pattern 110 may be formed on semiconductor substrate 100. Semiconductor substrate 100 may include a silicon substrate, a silicon on insulator (SOI) substrate, or other layers or materials, according to embodiments. Semiconductor substrate 100 may have an isolation area that may be formed with a trench isolation layer. Semiconductor substrate 100 may have an active area that may be formed with a device such as a transistor, and which may be defined by the isolation area.

Mask layer pattern 110 may include a photoresist film, in embodiments. Mask layer pattern 110 may be a hard mask layer pattern, in embodiments. If mask layer pattern 110 is a photoresist film, a photoresist film may be formed on semiconductor substrate 100, and then a typical exposure and development process may be performed. A photoresist pattern may thus be formed, which may expose the isolation area of the semiconductor substrate 100. Although a detailed description concerning a known manufacturing process is omitted here, if necessary, typical processes for forming a device, such as an ion implantation process, may be performed before forming mask layer pattern 110, according to embodiments.

After forming mask layer pattern 110, an organic material layer, such as bottom antireflective coating (BARC) layer 120, may be formed on a surface (for example, the entire surface) of the resultant structure. Bottom antireflective coating layer 120 may cover mask layer pattern 110 as well as semiconductor substrate 100. Bottom antireflective coating layer 120 may be formed through a known coating process.

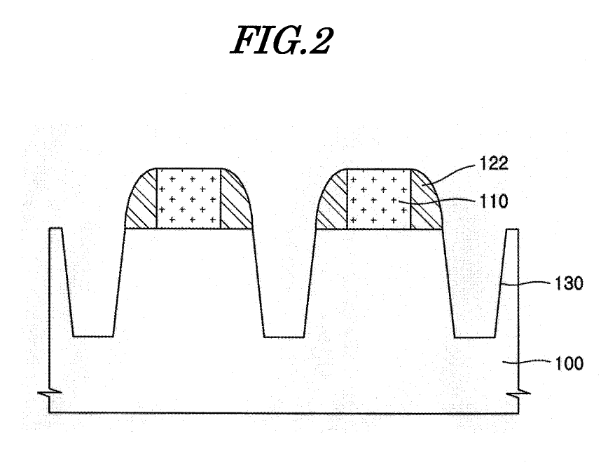

Referring to FIG. 2, an etching process may be sequentially performed with respect to bottom antireflective coating layer 120 and an exposed part of semiconductor substrate 100. This may form bottom antireflective spacer layer 122 and isolation trench 130. In embodiments, the etching process may include an anisotropic etching process such as an etch-back process. If an anisotropic etching process is performed, bottom antireflective coating layer 120, that may exist on upper surfaces of mask layer pattern 110 and semiconductor substrate 100, may be removed. Bottom antireflective coating layer 120, however, may remain at side surfaces of mask layer pattern 110 and may not be completely removed. This may form bottom antireflective spacer layer 122.

Due to bottom antireflective coating spacer layer 122, a width of an exposed surface of semiconductor substrate 100 may be reduced by a width of spacer layer 122. Accordingly, a width of isolation trench 130 may be reduced by the width of bottom antireflective spacer layer 122. A coating thickness of bottom antireflective coating layer 120 may be adjusted. It may therefore be possible to control the thickness of spacer layer 122. As a result, a thickness of isolation trench 130 may be more precisely controlled.

In embodiments, after forming isolation trench 130, a burial insulating layer may be filled in isolation trench 130, and may form a trench isolation layer having a narrow width.

According to embodiments, it may be possible to form an isolation trench having a width reduced by a width of a spacer layer formed by forming a mask layer pattern and a bottom antireflective coating layer and then etching the bottom antireflective coating layer through an etching process for the bottom antireflective coating layer and a semiconductor substrate.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a mask layer pattern over a semiconductor substrate;
forming an organic material layer over the semiconductor substrate and the mask layer pattern; and
forming an isolation trench in semiconductor substrate having a width defined by widths of the mask layer pattern and an organic material spacer layer formed by etching the organic material layer through an etching process.

2. The method of claim 1, wherein the organic material layer comprises a bottom antireflective coating (BARC) layer.

3. The method of claim 1, wherein the mask layer pattern comprises a photoresist film.

4. The method of claim 1, wherein the organic material layer and the semiconductor substrate are etched through an anisotropic etching process.

5. The method of claim 4, wherein the organic material layer and the semiconductor substrate are etched in a single etching process to form the spacer layer and the isolation trench.

6. The method of claim 1, wherein the mask layer pattern comprises a plurality of masks, each mask having spacer layers formed thereon, and wherein trenches are formed between each of the plurality of masks having spacer layers.

7. A device, comprising:
a semiconductor substrate;
a mask layer formed over the semiconductor substrate;
spacer layers formed on sides of the mask layer; and
a trench formed in the semiconductor substrate, wherein a width of the trench is defined by a width of the mask layer and a width the spacer layers.

8. The device of claim 7, further comprising a plurality of mask layers formed at prescribed intervals, each of the plurality of mask layers having spacer layers, wherein a trench is formed between spacer layers of the adjacent mask layers.

9. The device of claim 8, wherein the spacer layers comprise a bottom antireflective coating layer.

10. The device of claim 9, wherein the trench is formed by a dry etching process.

11. The device of claim 9, wherein the bottom antireflective coating layer is formed over an entire surface of the semiconductor substrate, and wherein the trench and the spacer layers are formed through a single etching process.

12. The device of claim 11, wherein the etching process comprises a dry etching process.

13. The device of claim 7, wherein the mask layer comprises one of a photoresist film and a hard mask layer.

14. A method, comprising:
forming a mask layer pattern over a semiconductor substrate;
forming spacer layers on side surfaces of the mask layer pattern; and
forming an isolation trench having a width defined by a combined width of the mask layer pattern and the spacer layer by etching the semiconductor substrate.

15. The method of claim 14, wherein the spacer layers are formed by covering the mask layer pattern within an organic material and performing an etchback process to remove portions of the organic material.

16. The method of claim 15, wherein the organic material comprises a bottom antireflective coating layer.

17. The method of claim 15, wherein the isolation trench and the spacer layers are formed by a single etching process.
